(19) United States
(12) Patent Application Publication
(10) Pub. No.: US 2025/0013266 A1
(43) Pub. Date: Jan. 9, 2025

(54) DISPLAY DEVICE

(71) Applicant: Samsung Display Co., LTD., Yongin-si (KR)

(72) Inventor: SUCHANG RYU, Yongin-si (KR)

(21) Appl. No.: 18/617,932

(22) Filed: Mar. 27, 2024

(30) Foreign Application Priority Data
Jul. 7, 2023 (KR) 10-2023-0088221

(51) Int. Cl. G06F 1/16

(52) U.S. Cl. CPC G06F 1/1656; G06F 1/1616

(57) ABSTRACT

A display device includes a display module, a support plate disposed below the display module, and a polymer film disposed below the support plate. The display module may include first and second non-bending regions, and a bending region therebetween. The support plate includes first and second glass substrates spaced apart from each other in one direction perpendicular to a thickness direction. The polymer film may include a first flat portion, a curved portion, which extends from the first flat portion and overlaps the bending region, and a second flat portion which extends from the curved portion and is spaced apart from the first flat portion. A state, in which the display module is bent such that the first non-bending region overlaps the second non-bending region, is defined as a first mode, and in the first mode, the curved portion is bent to have a curvature.

This application claims priority to Korean Patent Application No. 10-2023-0088221, filed on Jul. 7, 2023, and all the benefits accruing therefrom under 35 U.S.C. § 119, the content of which in its entirety is herein incorporated by reference.

### BACKGROUND

### 1. Field

The disclosure herein relates to a display device including a bending region.

### 2. Description of the Related Art

Various display devices used for multimedia devices such as a television, a mobile phone, a tablet computer, a navigation system, and a game console are being developed. A display device may include a display module which displays an image and senses an external input.

The display module may include a non-display region in which an image is not displayed and a circuit board, etc., are disposed. A portion of the display module may be bent to reduce a size of the non-display region.

### SUMMARY

In a display module where a portion thereof is bent to reduce a size of a non-display region, cracks may occur due to bending stress during bending, and a measure to prevent the occurrence of cracks may be desired.

Embodiments of the disclosure provide a display device which exhibits high impact resistance.

An embodiment of the invention provides a display device including: a display module including a first non-bending region, a bending region adjacent to the first non-bending region, and a second non-bending region spaced apart from the first non-bending region with the bending region therebetween; a support plate disposed below the display module, where the support plate includes a first glass substrate and a second glass substrate which are spaced apart from each other in one direction perpendicular to a thickness direction; and a polymer film disposed below of the support plate, where the polymer film includes a first flat portion, a curved portion, which extends from the first flat portion and overlaps the bending region, and a second flat portion which extends from the curved portion and is spaced apart from the first flat portion, where a state, in which the display module is bent such that the first non-bending region overlaps the second non-bending region, is defined as a first mode, and a state, in which the display module is not bent, is defined as a second mode, and in the first mode, the curved portion is bent to have a curvature.

In an embodiment, in the first mode, the curved portion may form a portion of a circumference of an oval, and a major axis of the oval may be parallel to the one direction.

In an embodiment, the bending region may be a non-display region in which an image is not displayed.

In an embodiment, in the first mode, the curved portion may be in contact with the display module, and in the second mode, the curved portion may be spaced apart from the display module.

In an embodiment, in the first mode, the first flat portion may overlap the second flat portion.

In an embodiment, a length of the curved portion of the polymer film may be greater than a length of the bending region of the display module.

In an embodiment, the display device may further include a first buffer layer disposed on the curved portion.

In an embodiment, in the polymer film, a first groove may be defined between the first flat portion and the curved portion, and a second groove may be defined between the second flat portion and the curved portion.

In an embodiment, in the thickness direction, the first groove and the second groove may be defined through only a portion of the polymer film.

In an embodiment, the display device may further include a second buffer layer disposed below the curved portion, wherein in the first mode, the second buffer layer may be disposed to fill an inner space formed by the curved portion.

In an embodiment, the display device may further include a sub-cushion layer disposed on the curved portion, where in the one direction, a length of the sub-cushion layer may be less than a minimum spacing distance between the first glass substrate and the second glass substrate.

In an embodiment, a thickness of the sub-cushion layer may be less than a thickness of the support plate.

In an embodiment, the display device may further include a lower module disposed on below the polymer film, wherein in the first mode, at least a portion of the lower module may be in contact with the polymer film.

In an embodiment, the first glass substrate may overlap the first non-bending region, the second glass substrate may overlap the second non-bending region, and the first glass substrate and the second glass substrate may not overlap the bending region.

In an embodiment, each of the first glass substrate and the second glass substrate may include an upper surface, a lower surface opposite to the upper surface, and a side surface disposed between the upper surface and the lower surface, and the side surface may include a first sub-side surface inclined with respect to the upper surface, and a second sub-side surface inclined with respect to the first sub-side surface and the lower surface.

In an embodiment, the display device may further include a lower module disposed below the polymer film, wherein one side edge of the lower module may be disposed outside an edge at which the second sub-side surface and the lower surface are connected to each other.

In an embodiment, the polymer film may include at least one selected from polyethylene terephthalate (PET), polyimide, (PI), polycarbonate (PC), polyethylene (PE), polypropylene (PP), polysulfone (PSF), poly(methyl methacrylate) (PMMA), triacetyl cellulose (TAC), and cyclo olefin polymer (COP).

In an embodiment, the display device may further include a bending-protective layer disposed on the display module, wherein in the first mode, the bending-protective layer may be bent to have a curvature.

In an embodiment, in the first mode, the bending-protective layer may be spaced apart from the curved portion with the display module therebetween.

In an embodiment, the display module may include a base layer, a circuit layer disposed on the base layer, and a display element layer disposed on the circuit layer.

### BRIEF DESCRIPTION OF THE DRAWINGS

The above and other features of the invention will become more apparent by describing in further detail embodiments thereof with reference to the accompanying drawings, in which:

FIG. 1 is a perspective view illustrating a display device according to an embodiment;

FIG. 2 is an exploded perspective view illustrating a display device according to an embodiment;

FIG. 3 is an exploded perspective view illustrating a display device according to an embodiment;

FIG. 4A is a perspective view illustrating a display device according to an embodiment;

FIG. 4B is a view illustrating a state in which the display device illustrated in FIG. 4A is folded;

FIG. 5 is a cross-sectional view illustrating a portion taken along line I-I′ of FIG. 2;

FIG. 6 is a cross-sectional view illustrating a portion of a display device according to an embodiment;

FIG. 7 is a cross-sectional view illustrating a portion taken along line II-II′ of FIG. 2;

FIG. 8 is a cross-sectional view illustrating a portion taken along line III-III′ of FIG. 3;

FIG. 9A is a cross-sectional view illustrating a portion of a display device according to an embodiment;

FIG. 9B is a cross-sectional view illustrating a portion of a display device according to an embodiment;

FIG. 9C is a cross-sectional view illustrating a portion of a display device according to an embodiment;

FIG. 10A is a cross-sectional view illustrating a portion of a display device according to an embodiment;

FIG. 10B is a cross-sectional view illustrating a portion of a display device according to an embodiment;

FIG. 10C is a cross-sectional view illustrating a portion of a display device according to an embodiment;

FIG. 10D is a cross-sectional view illustrating a portion of a display device according to an embodiment;

FIG. 10E is a cross-sectional view illustrating a portion of a display device according to an embodiment;

FIG. 10F is a cross-sectional view illustrating a portion of a display device according to an embodiment;

FIG. 10G is a cross-sectional view illustrating a portion of a display device according to an embodiment; and

FIG. 10H is a cross-sectional view illustrating a portion of a display device according to an embodiment.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

In this specification, it will be understood that when an element (or region, layer, portion, or the like) is referred to as being “on”, “connected to” or “coupled to” another element, it may be directly disposed/connected/coupled to another element, or intervening elements may be disposed therebetween.

Like reference numerals or symbols refer to like elements throughout. In the drawings, the thickness, the ratio, and the dimension of the elements are exaggerated for effective description of the technical contents.

Although the terms first, second, etc., may be used to describe various elements, these elements should not be limited by these terms. These terms are only used to distinguish one element from another element. For example, a first element may be referred to as a second element, and similarly, a second element may also be referred to as a first element without departing from the scope of the invention.

Also, the terms such as “below”, “lower”, “above”, “upper” and the like, may be used for the description to describe one element's relationship to another element illustrated in the figures. It will be understood that the terms have a relative concept and are described on the basis of the orientation depicted in the figures.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which the disclosure belongs. Also, terms, such as those defined in commonly used dictionaries, should be interpreted as having a meaning that is consistent with their meaning in the context of the relevant art and should not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, a display device according to embodiments of the invention will be described with reference to the accompanying drawings.

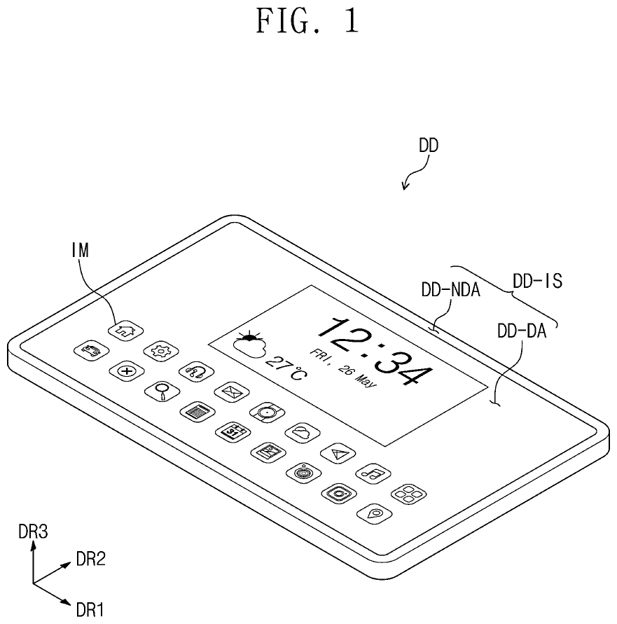

FIG. 1 is a perspective view illustrating a display device according to an embodiment.

Referring to FIG. 1, a display device DD according to an embodiment may be activated in response to an electrical signal. In an embodiment, for example, the display device DD may be a medium- and large-sized device such as a television, a monitor, an external billboard, a tablet computer, or a car navigation unit. Additionally, the display device DD may be a medium- and small-sized device such as a personal computer, a laptop computer, a personal digital terminal, a game console, a smartphone, and a camera. Also, these are merely presented as examples, and the display device DD may also be employed as other display devices without departing from the teachings herein.

The display device DD may display an image IM through a display surface DD-IS. The display surface DD-IS may be parallel to a plane defined by a first direction axis DR1 and a second direction axis DR2. FIG. 1 illustrates an embodiment of the display device DD provided as a flat display surface DD-IS, but an embodiment of the invention is not limited thereto. The display device DD may include a curved display surface or a three-dimensional display surface. The three-dimensional display surface may include a plurality of display regions which respectively indicate different directions.

The display surface DD-IS may include a display region DD-DA and a non-display region DD-NDA. The display device DD may display the image IM through the display region DD-DA. The non-display region DD-NDA may be adjacent to the display region DD-DA. In an embodiment, as shown in FIG. 1, the non-display region DD-NDA may surround the display region DD-DA. In an alternative embodiment, the non-display region DD-NDA may be disposed to be adjacent to only one side of the display region DD-DA or may be omitted.

In FIG. 1A and the following drawings, a first direction axis DR1 to a third direction axis DR3 are illustrated, and directions indicated by the first to third direction axes DR1, DR2, and DR3 described herein may have a relative concept and thus may be changed to other directions. In addition, the directions indicated by the first to third direction axes DR1, DR2, and DR3 may be referred to as first to third directions, and may be denoted as the same reference numerals or symbols. In this specification, the first direction axis DR1 and the second direction axis DR2 may be orthogonal to each other, and the third direction axis DR3 may be a normal direction of a plane defined by the first direction axis DR1 and the second direction axis DR2.

A thickness direction of the display device DD may be a direction parallel to the third direction axis DR3. An upper surface (or on) and a lower surface (or below) may be defined based on the third direction axis DR3. The upper surface (or on) means a surface (or direction) of getting closer to the display surface DD-IS, and the lower surface (or below) means a surface (or direction) of getting farther away from the display surface DD-IS. A cross section means a surface parallel to the thickness direction DR3, and a plane means a surface perpendicular to the thickness direction DR3. A plane means a flat surface defined by the first direction axis DR1 and the second direction axis DR2.

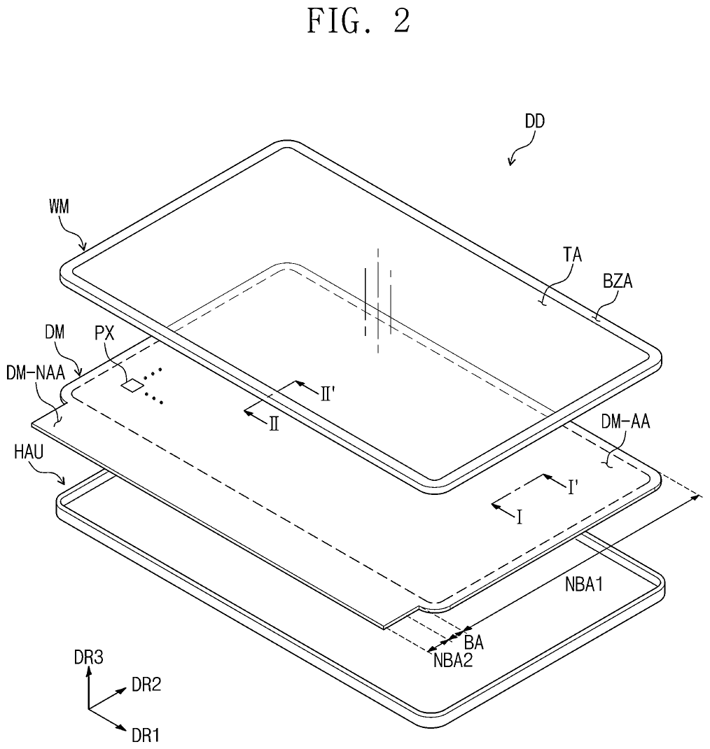

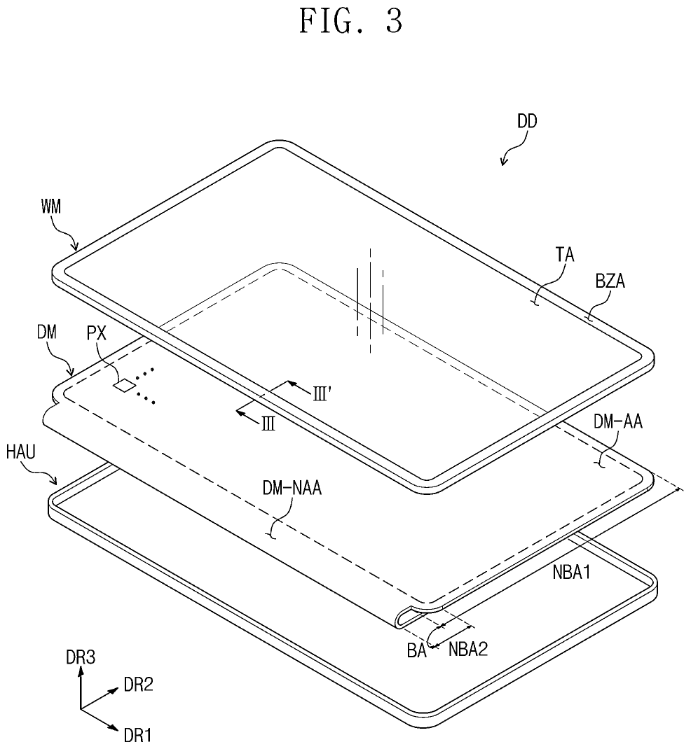

FIGS. 2 and 3 are exploded perspective views illustrating a display device DD according to an embodiment. In an embodiment, as shown in FIGS. 2 and 3, the display device DD may include a display module DM and a window member WM disposed on the display module DM. In such an embodiment, the display device DD may further include a housing HAU.

The window member WM may cover the entire exterior of the display module DM. The window member WM may include a transmission region TA and a bezel region BZA. A front surface of the window member WM including the transmission region TA and the bezel region BZA may correspond to a front surface of the display device DD. The transmission region TA may correspond to the display region DD-DA of the display device DD illustrated in FIG. 1, and the bezel region BZA may correspond to the non-display region DD-NDA of the display device DD illustrated in FIG. 1.

The transmission region TA may be an optically transparent region. The bezel region BZA may be a region having a relatively lower light transmittance than the transmission region TA. The bezel region BZA may have a predetermined color. In an embodiment, as shown in FIGS. 2 and 3, the bezel region BZA may be adjacent to the transmission region TA and surround the transmission region TA. The bezel region BZA may define a shape of the transmission region TA. However, an embodiment of the invention is not limited thereto. In an embodiment, the bezel region BZA may be disposed adjacent to only one side of the transmission region TA, or a portion thereof may be omitted.

The housing HAU may include a material having relatively high rigidity. In an embodiment, for example, the housing HAU may include a frame and/or plate composed of glass, plastic, or metal. The frame and/or plate may be provided in plurality. The housing HAU may provide a predetermined accommodation space. The display module DM may be accommodated inside the accommodation space and protected against an external impact.

The display module DM may be configured to generate an image and detect an external input applied from the outside. An active region DM-AA and a peripheral region DM-NAA may be defined in the display module DM. The active region DM-AA may correspond to the display region DD-DA illustrated in FIG. 1, and the peripheral region DM-NAA may correspond to the non-display region DD-NDA illustrated in FIG. 1.

The active region DM-AA may be activated in response to an electrical signal. The peripheral region DM-NAA may be located to be adjacent to at least one side of the active region DM-AA. The peripheral region DM-NAA may be disposed to surround the active region DM-AA. However, an embodiment of the invention is not limited thereto, and alternatively, a portion of the peripheral region DM-NAA may be omitted. A driving circuit, a driving line, or the like for driving the active region DM-AA may be disposed in the peripheral region DM-NAA.

A plurality of pixels PX may be arranged in the active region DM-AA. The plurality of pixels PX may include a red pixel, a green pixel, and a blue pixel and further include a white pixel according to an embodiment.

The display module DM may be bent and accommodated inside the housing HAU. The display module DM may include a first non-bending (or flat) region NBA1, a bending region BA, and a second non-bending region NBA2. The bending region BA and the second non-bending region NBA2 may be included in the peripheral region DM-NAA. The bending region BA and the second non-bending region NBA2 may correspond to the non-display region DD-NDA illustrated in FIG. 1. The bending region BA and the second non-bending region NBA2 may be regions in which a video and an image are not displayed.

The first non-bending region NBA1 and the second non-bending region NBA2 may be spaced apart from each other with the bending region BA therebetween. The second non-bending region NBA2, the bending region BA, and the first non-bending region NBA1 may be sequentially disposed or defined in the second direction DR2. When viewed on a plane (or in a plan view or in the third direction DR3), the area of the first non-bending region NBA1 may be greater than the area of the bending region BA and the area of the second non-bending region NBA2. In a state in which the bending region BA is bent, at least a portion of the second non-bending region NBA2 may overlap to the first non-bending region NBA1. In this specification, it will be understood that when an element is referred to as overlapping another element, it is not limited to a case of having a same area or shape, and also may include a case of having different areas and/or shapes.

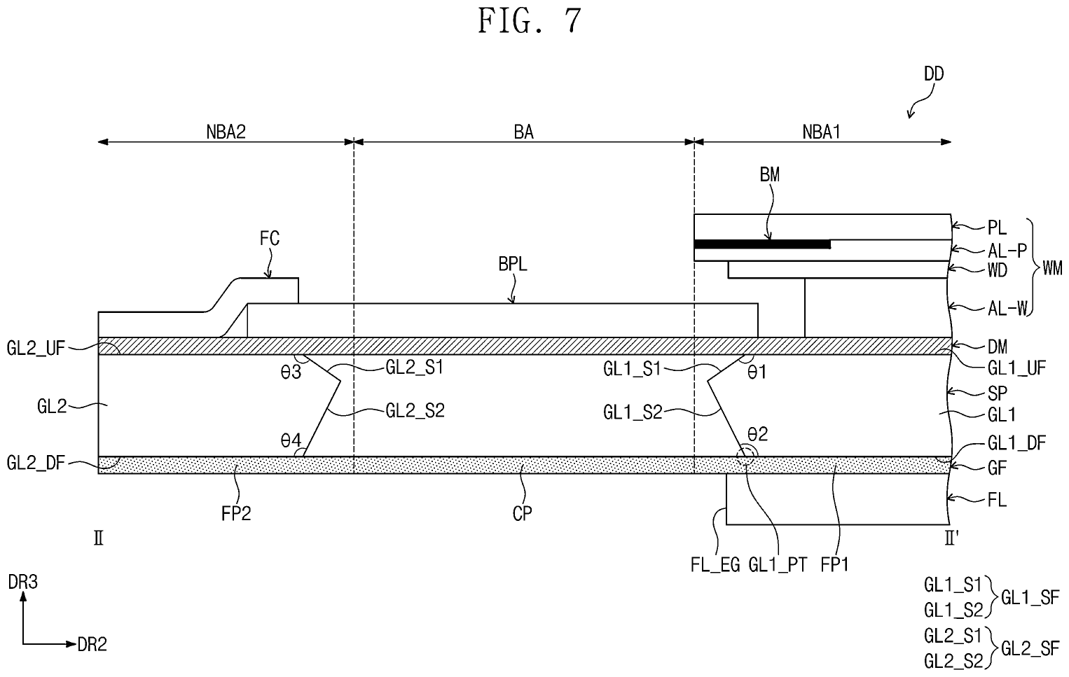

FIG. 2 is a perspective view illustrating a second mode in which a display module DM is not bent, and FIG. 3 is a perspective view illustrating a first mode in which the display module DM is bent. A state, in which the display module DM is bent by bending the bending region BA such that the first non-bending region NBA1 overlaps the second non-bending region NBA2, may be defined as the first mode (or a first state), and a state, in which the display module DM is not bent, may be defined as the second mode (or a second state). The display device DD according to an embodiment may include a polymer film GF (see FIG. 7) which is bent to have a curvature in the first mode. Therefore, the display device DD according to an embodiment may effectively prevent a crack from occurring in the bending region BA, and exhibit high impact resistance. The polymer film GF (see FIG. 7) will be described later in greater detail.

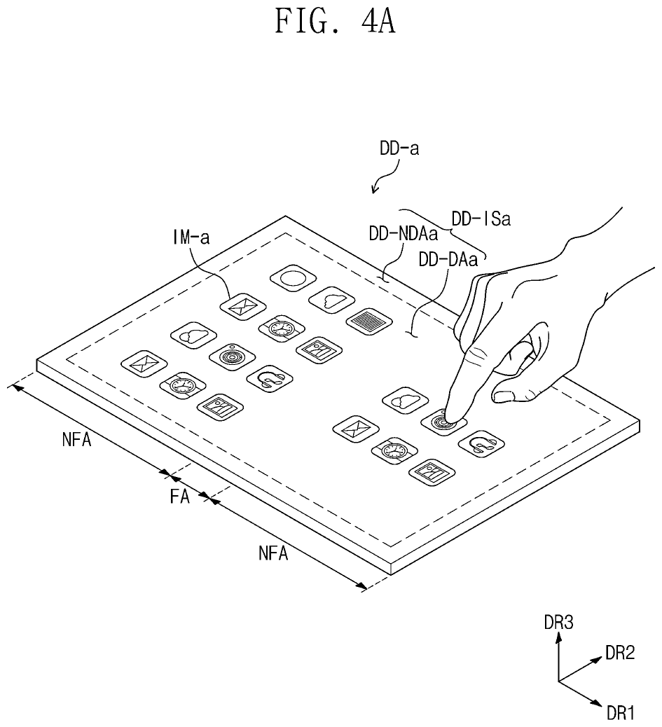

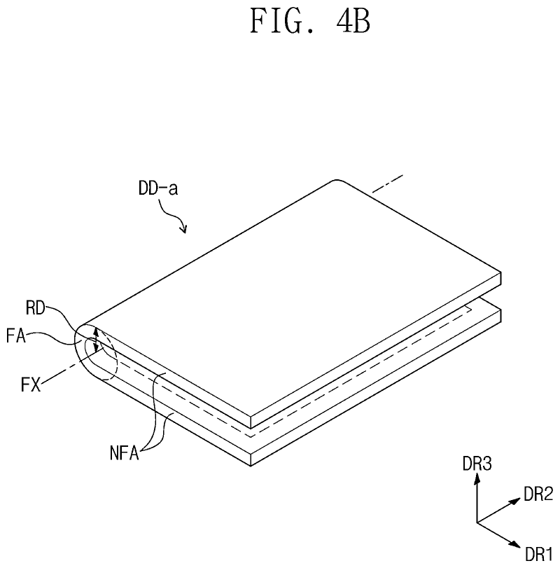

FIG. 4A is a perspective view illustrating a display device DD-a according to an embodiment of the invention. FIG. 4B is a view illustrating a state in which the display device DD-a illustrated in FIG. 4A is bent.

Referring to FIG. 4A, in an embodiment, the display device DD-a may have a rectangular shape which has long sides extending in a direction of the first direction axis DR1 and short sides extending in a direction of the second direction axis DR2 crossing the first direction axis DR1. However, an embodiment of the invention is not limited thereto, and the display device DD-a may have various shapes such as a circular shape and a polygonal shape on a plane. The display device DD-a may be a flexible display device.

The display device DD-a according to an embodiment may include at least one folding region FA. Referring to FIGS. 4A and 4B, an embodiment of the display device DD-a may include the folding region FA and a plurality of non-folding regions NFA. The folding region FA may be disposed between the non-folding regions NFA, and the folding region FA and the non-folding regions NFA may be disposed to be adjacent to each other in the direction of the first direction axis DR1.

FIGS. 4A and 4B illustrate an embodiment including a single folding region FA and two non-folding regions NF, but the number of the folding region FA and the number of the non-folding regions NFA are not limited thereto. In an embodiment, for example, the display device DD-a may include three or more non-folding regions NFA and a plurality of folding regions FA disposed between the non-folding regions NFA.

A display surface DD-ISa of the display device DD-a may include a display region DD-DAa and a non-display region DD-NDAa around the display region DD-DAa. The display region DD-DAa may display an image IM-a, and the non-display region DD-NDAa may not display the image IM-a. The non-display region DD-NDAa may surround the display region DD-DAa and define a border of the display device DD-a.

The display device DD-a may be a flexible display device capable of being repeatedly folded and unfolded. In an embodiment, for example, the folding region FA is bent (or bendable) with respect to a folding axis FX parallel to the second direction axis DR2 and the display device DD-a may be folded (or foldable). The folding axis FX may be defined as a short axis parallel to a short side of the display device DD-a. However, an embodiment of the invention is not limited thereto, and the folding axis may be a long axis parallel to a long side of the display device DD-a. Alternatively, the folding axis may be parallel to the first direction DR1.

When the display device DD-a is folded, the display device DD-a may be in-folded such that the non-folding regions NFA may face each other and the display surface DD-ISa is not exposed to the outside. However, an embodiment of the invention is not limited thereto, and the display device DD-a may be out-folded such that the display surface DD-ISa is exposed to the outside.

The folding region FA may be a portion deformable into a form folded with respect to the folding axis FX parallel to the second direction axis DR2. In an embodiment, for example, the folding region FA may have a curvature radius RD of 5 mm or less.

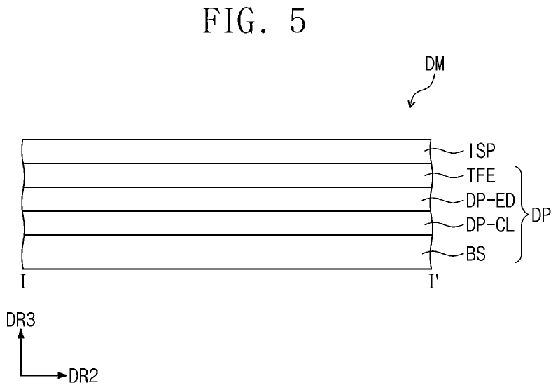

Hereinafter, for convenience of description, features of embodiments of the display device DD illustrated in FIGS. 1 to 3 will be described in detail, but it would be understood that such features of the display device DD may be similarly applied to the display device DD-a illustrated in FIGS. 4A and 4B. FIG. 5 is a cross-sectional view illustrating a portion taken along line I-I′ of FIG. 2. FIG. 5 is a cross-sectional view illustrating a display module DM according to an embodiment.

Referring to FIG. 5, an embodiment of the display module DM may include a display panel DP and an input-sensing layer ISP disposed on the display panel DP. The display panel DP may be configured to substantially generate an image.

The display panel DP may include a base layer BS, a circuit layer DP-CL, a display element layer DP-ED, and an encapsulation layer TFE which are sequentially stacked. In an embodiment, a functional layer (not shown) may be further disposed between two adjacent layers among the base layer BS, the circuit layer DP-CL, the display element layer DP-ED, and the encapsulation layer TFE.

The base layer BS may provide a base surface on which the circuit layer DP-CL is disposed. The base layer BS may be a flexible substrate which is bendable, foldable, rollable, or the like. The base layer BS may be a glass substrate, a metal substrate, a polymer substrate, or like. However, an embodiment of the invention is not limited thereto, and the base layer BS may include an inorganic layer, an organic layer, or a composite material layer.

The base layer BS may have a single-layered or multi-layered structure. In an embodiment, for example, the base layer BS may include a first synthetic resin layer, a multi-layered or single-layered inorganic layer, or a second synthetic resin layer disposed on the multi-layered or single-layered inorganic layer. In an embodiment, the first synthetic resin layer and the second synthetic resin layer may each include a polyimide-based resin. In an embodiment, the first synthetic resin layer and the second synthetic resin layer may each include at least one selected from an acryl-based resin, a methacryl-based resin, a polyisoprene-based resin, a vinyl-based resin, an epoxy-based resin, a urethane-based resin, a cellulose-based resin, a siloxane-based resin, a polyamide-based resin, and a perylene-based resin. In this specification, a “˜˜based” resin may be considered as including a functional group of “˜˜”.

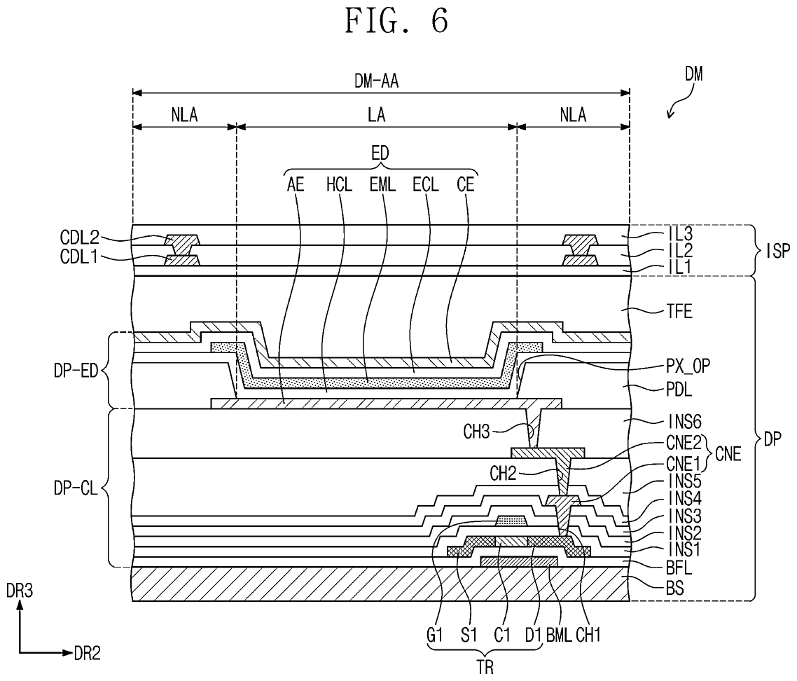

The circuit layer DP-CL may be disposed on the base layer BS. The circuit layer DP-CL may include an insulating layer, a semiconductor pattern, a conductive pattern, a signal line, or the like. The display element layer DP-ED may be disposed on the circuit layer DP-CL. The display element layer DP-ED may include a light-emitting element ED to be described later (see FIG. 6). In an embodiment, for example, the light-emitting element ED (see FIG. 6) may include an organic light-emitting material, an inorganic light-emitting material, an organic-inorganic light-emitting material, quantum dots, quantum rods, a micro light emitting diode (LED), or a nano LED.

The encapsulation layer TFE may be disposed on the display element layer DP-ED. The encapsulation layer TFE may protect the display element layer DP-ED against moisture, oxygen, and foreign substances such as dust particles. The encapsulation layer TFE may include at least one inorganic layer. In an embodiment, for example, the encapsulation layer TFE may include an inorganic layer, an organic layer, and an inorganic layer which are sequentially stacked.

The input-sensing layer ISP may be disposed on the display panel DP. The input-sensing layer ISP may be disposed on the encapsulation layer TFE. In an embodiment, the input-sensing layer ISP may be directly disposed or formed on the encapsulation layer TFE. In an embodiment, an adhesive member may be disposed between the input-sensing layer ISP and the display panel DP.

In this specification, the wording, “an element is directly disposed on (or below) of another element” means that intervening elements are not disposed therebetween. That is, the wording, “an element is ‘directly disposed on’ (or below) of another element” means that the element is “in contact with” the other element.

The input-sensing layer ISP may detect an external input, change the detected external input to a predetermined input signal, and provide the input signal to the display panel DP. In an embodiment, for example, the input-sensing layer ISP may be a touch-sensing layer which detects a touch. The input-sensing layer ISP may recognize a direct touch by a user, an indirect touch by a user, a direct touch by an object, or an indirect touch by an object.

The input-sensing layer ISP may detect at least one of a position or intensity (pressure) of a touch applied from the outside. The input-sensing layer ISP may have various structures or be composed of various materials, but is not limited to any one embodiment. In an embodiment, for example, the input-sensing layer ISP may detect an external input in a capacitive manner. The display panel DP may receive input signals from the input-sensing layer ISP and generate images corresponding the input signals.

in an embodiment, the display module DM may further include an optical layer (not shown) disposed on the display panel DP. The optical layer may be disposed on the display panel DP and control the reflected light of external light on the display panel DP. In an embodiment, for example, the optical layer may include a polarizing plate or a color filter layer.

FIG. 6 is a cross-sectional view illustrating a display module DM. FIG. 6 may be a cross-sectional view describing, in greater detail, a configuration of the display module DM illustrated in FIG. 5.

The display panel DP may include the pixel PX (see FIGS. 2 and 3). The pixel PX (see FIGS. 2 and 3) may include a transistor TR and a light-emitting element ED. The transistor TR and the light-emitting element ED may be disposed on the base layer BS. For convenience of illustration, FIG. 6 illustrates one transistor TR of the pixel PX, but the pixel PX (see FIGS. 2 and 3) may substantially include a plurality of transistors for driving the light-emitting element ED and at least one capacitor.

The circuit layer DP-CL may be disposed on the base layer BS. The circuit layer DP-CL may include a shielding electrode BML, a transistor TR, a connection electrode CNE, and a plurality of insulating layers BFL and INS1 to INS6. The plurality of insulating layers BFL and INS1 to INS6 may include a buffer layer BFL and first to sixth insulating layers INS1 to INS6. However, the stacked structure of the circuit layer DP-CL illustrated in FIG. 6 is merely an example, and the stacked structure of the circuit layer DP-CL may be changed according to a configuration of the pixel PX (see FIGS. 2 and 3) and a process for the circuit layer DP-CL.

The shielding electrode BML may be disposed on the base layer BS. The shielding electrode BML may overlap the transistor TR. The shielding electrode BML may block light incident onto the transistor TR from below the display panel DP to protect the transistor TR. The shielding electrode BML may include a conductive material. When a voltage is applied to the shielding electrode BML, a threshold voltage of the transistor TR disposed on the shielding electrode BML may be maintained. However, an embodiment of the invention is not limited thereto, and the shielding electrode BML may be a floating electrode. Alternatively, the shielding electrode BML may be omitted.

The buffer layer BFL may be disposed on the base layer BS and cover the shielding electrode BML. The buffer layer BFL may include an inorganic layer. The buffer layer BFL may improve a bonding force between the base layer BS and a semiconductor pattern or a conductive pattern, which is disposed on the buffer layer BFL.

The transistor TR may include a source S1, a channel C1, a drain D1, and a gate G1. The source S1, the channel C1, and the drain D1 of the transistor TR may be formed from a semiconductor pattern. The semiconductor pattern of the transistor TR may include polysilicon, amorphous silicon, or a metal oxide. However, any material having semiconductor properties may be used without being limited thereto.

The semiconductor pattern may include a plurality of regions divided based on a conductivity level. In the semiconductor pattern, a region, which is doped with a dopant or in which a metal oxide is reduced, may have a high conductivity, and may serve substantially as a source electrode and a drain electrode of the transistor TR. A highly conductive region of the semiconductor pattern may correspond to the source S1 and the drain D1 of the transistor TR. In the semiconductor pattern, a region, which is undoped or lightly doped or which has a low conductivity due to a non-reduced metal oxide, may correspond to the channel C1 (or active) of the transistor TR.

The first insulating layer INS1 may cover the semiconductor pattern of the transistor TR and be disposed on the buffer layer BFL. The gate G1 of the transistor TR may be disposed on the first insulating layer INS1. The gate G1 may overlap the channel C1 of the transistor TR. The gate G1 may function as a mask during the process of doping the semiconductor pattern of the transistor TR.

The second insulating layer INS2 may cover the gate G1 and be disposed on the first insulating layer INS1. The third insulating layer INS3 may be disposed on the second insulating layer INS2.

The connection electrode CNE may include a first connection electrode CNE1 and a second connection electrode CNE2 which are electrically connect the transistor TR and the light-emitting element ED. However, a configuration of the connection electrode CNE which electrically connects the transistor TR to the light-emitting element ED is not limited thereto. In an embodiment, the first connection electrode CNE1 or the second connection electrode CNE2 may be omitted, or an additional connection electrode may be further included.

The first connection electrode CNE1 may be disposed on the third insulating layer INS3. The first connection electrode CNE1 may be connected to the drain D1 via a first contact hole CH1 defined through the first to third insulating layers INS1 to INS3. The fourth insulating layer INS4 may cover the first connection electrode CNE1 and be disposed on the third insulating layer INS3. The fifth insulating layer INS5 may be disposed on the fourth insulating layer INS4.

The second connection electrode CNE2 may be disposed on of the fifth insulating layer INS5. The second connection electrode CNE2 may be connected to the first connection electrode CNE1 via a second contact hole CH2 passing through the fourth and fifth insulating layers INS4 and INS5. The sixth insulating layer INS6 may cover the second connection electrode CNE2 and be disposed on the fifth insulating layer INS5.

The first to sixth insulating layers INS1 to INS6 may each include an inorganic layer or an organic layer. In an embodiment, for example, the inorganic layer may include at least one selected from aluminum oxide, titanium oxide, silicon oxide, silicon oxynitride, zirconium oxide, and hafnium oxide. The organic layer may include at least one selected from an acryl-based resin, a methacryl-based resin, a polyisoprene-based resin, a vinyl-based resin, an epoxy-based resin, a urethane-based resin, a cellulose-based resin, a siloxane-based resin, a polyamide-based resin, and a perylene-based resin.

The display element layer DP-ED may include a pixel-defining film PDL and a light-emitting element ED. The light-emitting element ED may include a first electrode AE, a hole control layer HCL, a light-emitting layer EML, an electron control layer ECL, and a second electrode CE.

The first electrode AE may be disposed on the sixth insulating layer INS6. The first electrode AE may be connected to the second connection electrode CNE2 via a third contact hole CH3 defined through the sixth insulating layer INS6. The first electrode AE may be electrically connected to the drain D1 of the transistor TR via the first and second connection electrodes CNE1 and CNE2.

The pixel-defining film PDL may be disposed on the sixth insulating layer INS6. A light-emitting opening PX_OP, which exposes a portion of the first electrode AE, may be defined in the pixel-defining film PDL. A portion, of the first electrode AE, which is exposed by the light-emitting opening PX_OP, may be defined as a light-emitting region LA.

A region, in which the pixel-defining film PDL is disposed, may correspond to a non-light-emitting region NLA. The non-light-emitting region NLA may surround, in an active region DM-AA, the light-emitting region LA.

The hole control layer HCL may be disposed on the first electrode AE and the pixel-defining film PDL. The hole control layer HCL may be provided as a common layer overlapping the light-emitting region LA and the non-light-emitting region NLA. The hole control layer HCL may include at least one of a hole transport layer, a hole injection layer, or an electron blocking layer.

The light-emitting layer EML may be disposed on the hole control layer HCL. In an embodiment, as shown in FIG. 6, the light-emitting layer EML may be disposed in a region corresponding to the light-emitting opening PX_OP. Alternatively, the light-emitting layer EML may be provided as a common layer. The light-emitting layer EML may include an organic light-emitting material and/or an inorganic light-emitting material. The light-emitting layer EML may emit light having one color of red, green, or blue.

The electron control layer ECL may be disposed on the light-emitting layer EML. The electron control layer ECL may be provided as a common layer overlapping the light-emitting region LA and the non-light-emitting region NLA. The electron control layer ECL may include at least one selected from an electron transport layer, an electron injection layer, and a hole blocking layer.

The second electrode CE may be disposed on the electron control layer ECL. The second electrode CE may be provided as a common layer overlapping the light-emitting region LA and the non-light-emitting region NLA. The second electrode CE may be disposed, in common, in the pixels PX (see FIGS. 2 and 3) and apply voltages to the pixels PX (see FIGS. 2 and 3).

An encapsulation layer TFE may be disposed on the second electrode CE and cover the light-emitting element ED. The encapsulation layer TFE may include a plurality of thin films. In an embodiment, for example, the encapsulation layer TFE may include inorganic films, disposed on the second electrode CE, and an organic film disposed between the inorganic films. The inorganic film may protect the light-emitting element ED against moisture/oxygen, and the organic film may protect the light-emitting element ED against foreign substances such as dust particles.

The input-sensing layer ISP may include a first sensing-insulating layer IL1, a second sensing-insulating layer IL2, and a third sensing-insulating layer IL3. The input-sensing layer ISP may include at least one conductive layer disposed on of the sensing-insulating layers. The input-sensing layer ISP may include a first conductive layer CDL1, and a second conductive layer CDL2.

The first sensing-insulating layer IL1 may be disposed on the encapsulation layer TFE. The first sensing-insulating layer IL1 may include at least one or more inorganic insulating layers. In an embodiment, the first sensing-insulating layer IL1 may be in contact with the encapsulation layer TFE. Alternatively, the first sensing-insulating layer IL1 may be omitted, and in this case, the first conductive layer CDL1 may be in contact with the encapsulation layer TFE.

The first conductive layer CDL1 may be disposed on the first sensing-insulating layer IL1. The first conductive layer CDL1 may include a plurality of first conductive patterns. The plurality of first conductive patterns may be disposed on the first sensing-insulating layer IL1. The second sensing-insulating layer IL2 may be disposed on the first sensing-insulating layer IL1 to cover at least a portion of the first conductive layer CDL1.

The second conductive layer CDL2 may be disposed on the second sensing-insulating layer IL2. The second conductive layer CDL2 may include a plurality of second conductive patterns. The plurality of second conductive patterns may be disposed on the second sensing-insulating layer IL2. The plurality of second conductive patterns may be respectively connected to the plurality of first conductive patterns via the contact hole defined or formed in the second sensing-insulating layer IL2.

The plurality of first conductive patterns of the first conductive layer CDL1 and the plurality of second conductive patterns of the second conductive layer CDL2 may each be disposed to correspond to the non-light-emitting region NLA. The plurality of first conductive patterns of the first conductive layer CDL1 and the plurality of second conductive patterns of the second conductive layer CDL2 may each correspond to a mesh pattern.

The third sensing-insulating layer IL3 may be disposed on the second sensing-insulating layer IL2 and cover the second conductive layer CDL2. The second sensing-insulating layer IL2 and the third sensing-insulating layer IL3 may each include an inorganic insulating layer or an organic insulating layer.

The first conductive layer CDL1 and the second conductive layer CDL2 may each have a single-layered structure or a multi-layered structure in which layers are stacked along the third direction DR3. The conductive layers CDL1 and CDL2 having a single-layered structure may each include a metal layer or a transparent conductive layer. The metal layer may include molybdenum, silver, titanium, copper, aluminum, or an alloy thereof. The transparent conductive layer may include a transparent conductive oxide such as indium tin oxide (ITO), indium zinc oxide (IZO), zinc oxide (ZnO), or indium zinc tin oxide (IZTO). Additionally, the transparent conductive layer may include a conductive polymer such as poly(3,4-ethylenedioxythiophene) (PEDOT), a metal nanowire, graphene, or the like.

The conductive pattern layers CDL1 and CDL2 having a multi-layered structure may include metal layers. In an embodiment, for example, the metal layers may have a three-layered structure of titanium (Ti)/aluminum (Al)/titanium (Ti). In an embodiment, the conductive pattern layers CDL1 and CDL2 having a multi-layered structure may each include at least one metal layer and at least one transparent conductive layer.

FIG. 7 is a cross-sectional view illustrating a portion taken along line II-II′ of FIG. 2. In FIG. 7, the housing HAU (see FIG. 2) is omitted for convenience of illustration and description. FIG. 7 may be a cross-sectional view illustrating a display device DD in a second mode. A display module DM may be in a flat (or unbent) state in the second mode.

Referring to FIG. 7, in an embodiment of the display device DD, a window member WM may be disposed on the display module DM. The window member WM may include a window WD, a protective layer PL, and a printed layer BM. Additionally, the window member WM may further include a window adhering layer AL-W, disposed between the display module DM and the window WD, and a protective layer adhering layer AL-P disposed between the window WD and the protective layer PL.

The window member WM may overlap a first non-bending region NBA1 in the thickness direction DR3. The window member WM may not overlap a bending region BA and a second non-bending region NBA2.

The window adhering layer AL-W may bond the display module DM and the window WD to each other. The protective layer adhering layer AL-P may bond the window WD and the protective layer PL to each other. The window adhering layer AL-W and the protective layer adhering layer AL-P may each include a typical bonding agent such as a pressure sensitive adhesive (PSA), an optically clear adhesive (OCA), or an optical clear resin (OCR), but not being limited thereto. Alternatively, at least one of the window adhering layer AL-W or the protective layer adhering layer AL-P may be omitted.

The printed layer BM may overlap the non-display region DD-NDA illustrated in FIG. 1. The printed layer BM may be disposed on one surface of the protective layer PL or one surface of the window WD. FIG. 7 illustrates an embodiment where the printed layer BM is disposed on a lower surface of the protective layer PL. One side edge of the printed layer BM may be parallel, in the third direction DR3, to one side edge of the protective layer PL. The printed layer BM is a colored light-shielding film, and for example, may be formed through coating. The printed layer BM may be formed by providing a base material and a dye or pigment mixed with the base material.

One side edge of the window WD may be disposed more inward toward the display device DD than one side edge of the protective layer PL is. The window WD may include a polymer substrate or a glass substrate. In an embodiment, for example, the window WD may include a glass substrate. The image IM (see FIG. 1) generated from the display module DM may pass through the window WD and be provided to a user. In an embodiment, for example, the window WD may include ultra-thin glass (UTG).

The protective layer PL may be a functional layer which protects one surface of the window WD. The protective layer PL may include a polymer film. The protective layer PL may include an anti-fingerprint coating agent, a hard coating agent, an antistatic agent, or the like.

A bending-protective layer BPL may be disposed on the display module DM. The bending-protective layer BPL may overlap the bending region BA in the thickness direction DR3. Additionally, the bending-protective layer BPL may overlap the first non-bending region NBA1 and the second non-bending region NBA2. The length of the bending-protective layer BPL may be shorter than the length of the display module DM in the second direction DR2 perpendicular to the thickness direction DR3. In the second direction DR2, the length of a portion, of the bending-protective layer BPL, which overlaps the first non-bending region NBA1 may be shorter than the length of the first non-bending region NBA1. In the second direction DR2, the length of a portion, of the bending-protective layer BPL, which overlaps the second non-bending region NBA2 may be shorter than the length of the second non-bending region NBA2.

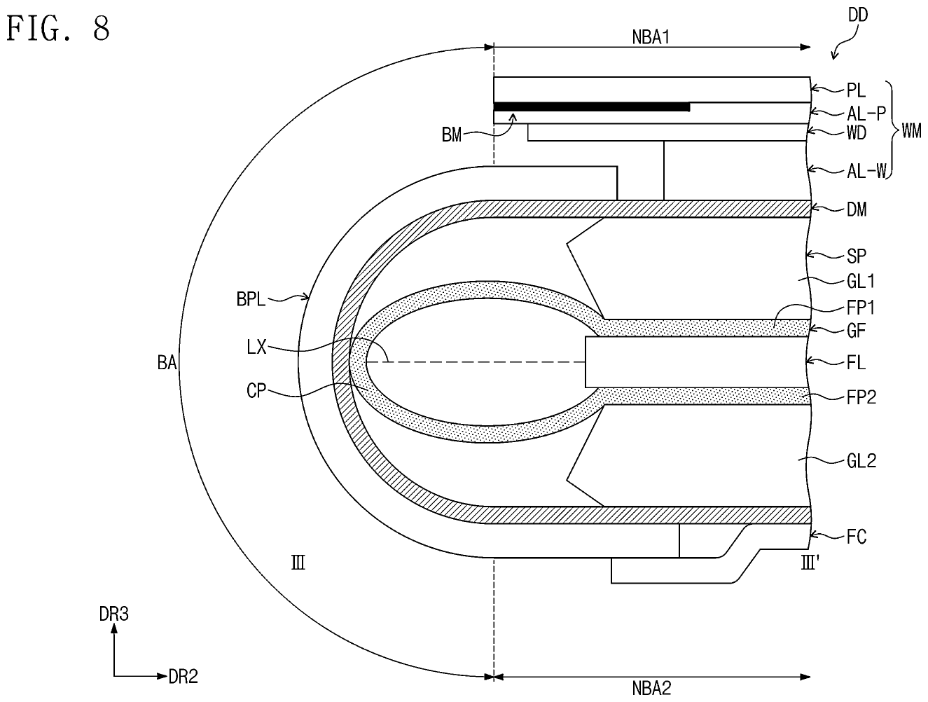

The bending-protective layer BPL (see FIG. 8) may be bent to have a curvature. The bending-protective layer BPL may protect the bending region BA against an external impact and control a neutral surface of the bending region BA. The bending-protective layer BPL may control a stress in the bending region BA such that the neutral surface becomes closer to signal lines arranged in the bending region BA. In an embodiment, for example, the bending-protective layer BPL may include an organic material such as polyimide, acrylate, or epoxy. The bending-protective layer BPL may be attached in a form of a protective film. However, this is illustrated as an example, and a material, included in the bending-protective layer BPL, and a form of the bending-protective layer BPL are not limited thereto.

A circuit board FC may be disposed on the display module DM. The circuit board FC may be a flexible printed circuit board. The circuit board FC may generate an electrical signal provided to the display module DM, or receive a signal generated from the display module DM, and may calculate a resultant value including information about the position, at which an input applied from the outside is detected, or about the strength of the input. A portion of the circuit board FC may be disposed on the bending-protective layer BPL. The circuit board FC may overlap the second non-bending region NBA2 in the thickness direction DR3. The circuit board FC may not overlap the bending region BA. In the second mode illustrated in FIG. 7, the circuit board FC may not overlap the first non-bending region NBA1. In the first mode illustrated in FIG. 8 to be described later, the circuit board FC may overlap the first non-bending region NBA1.

A support plate SP may be disposed below the display module DM. The support plate SP may be disposed below the display module DM. The support plate SP may overlap the first non-bending region NBA1 and the second non-bending region NBA2. The support plate SP may not overlap the bending region BA. The support plate SP may include a first glass substrate GL1 and a second glass substrate GL2 which are spaced apart from each other. In the second mode, the first glass substrate GL1 and the second glass substrate GL2 may be spaced apart from each other in the second direction DR2 perpendicular to the thickness direction DR3. The first glass substrate GL1 may overlap the first non-bending region NBA1. The second glass substrate GL2 may overlap the second non-bending region NBA2. The first glass substrate GL1 and the second glass substrate GL2 may not overlap the bending region BA.

The first glass substrate GL1 and the second glass substrate GL2 may be directly disposed below the bending region DM. In a typical or conventional display device, a protective film is directly disposed below a display module. The protective film is provided to protect the display module against an external impact. A typical or conventional method of manufacturing a display device includes providing a glass substrate as a carrier substrate below a display module, removing the provided glass substrate, and providing a protective film.

In the display device DD according to an embodiment of the invention, the first glass substrate GL1 and the second glass substrate GL2 are directly disposed below the display module DM, and the first glass substrate GL1 and the second glass substrate GL2 may be an unremoved carrier substrate provided during the manufacturing process. Therefore, the method of manufacturing the display device DD may not include removing a glass substrate and providing a protective film, thereby reducing manufacturing costs and improving manufacturing efficiencies.

The first glass substrate GL1 may include an upper surface GL1_UF, a lower surface GL1_DF opposite to the upper surface GL1_UF, and a side surface GL1_SF disposed between the upper surface GL1_UF and the lower surface GL1_DF. The upper surface GL1_UF, the side surface GL1_SF, and the lower surface GL1_DF may have an integral shape. The upper surface GL1_UF of the first glass substrate GL1 may be adjacent to the display module DM, and the lower surface GL1_DF of the first glass substrate GL1 may be adjacent to the polymer film GF. The side surface GL1_SF of the first glass substrate GL1 may include a first sub-side surface GL1_S1 and a second sub-side surface GL1_S2.

In the first glass substrate GL1, the first sub-side surface GL1_S1 may be inclined with respect to the upper surface GL1_UF. In the first glass substrate GL1, an angle θ1 between the first sub-side surface GL1_S1 and the upper surface GL1_UF may be greater than 90° and less than 180°. In the first glass substrate GL1, the second sub-side surface GL1_S2 may be inclined with respect to the lower surface GL1_DF and the first sub-side surface GL1_S1. In the first glass substrate GL1, an angle θ2 between the second sub-side surface GL1_S2 and the lower surface GL1_DF may be greater than 90° and less than 180°.

The second glass substrate GL2 may include an upper surface GL2_UF, a lower surface GL2_DF facing the upper surface GL2_UF, and a side surface GL2_SF disposed between the upper surface GL2_UF and the lower surface GL2_DF. The upper surface GL2_UF of the second glass substrate GL2 may be adjacent to the display module DM, and the lower surface GL2_DF of the second glass substrate GL2 may be adjacent to the polymer film GF. The side surface GL2_SF of the second glass substrate GL2 may include a first sub-side surface GL2_S1 and a second sub-side surface GL2_S2.

In the second glass substrate GL2, the first sub-side surface GL2_S1 may be inclined with respect to the upper surface GL2_UF. In the second glass substrate GL2, an angle θ3 between the first sub-side surface GL2_S1 and the upper surface GL2_UF may be greater than 90° and less than 180°. In the second glass substrate GL2, the second sub-side surface GL2_S2 may be inclined with respect to the lower surface GL2_DF and the first sub-side surface GL2_S1. In the second glass substrate GL2, an angle θ4 between the second sub-side surface GL2_S2 and the lower surface GL2_DF may be greater than 90° and less than 180°.

The side surface GL1_SF of the first glass substrate GL1 and the side surface GL2_SF of the second glass substrate GL2 may be reflective (e.g., left-right) symmetrical with each other in the second mode. The first glass substrate GL1 and the second glass substrate GL2 may be formed by etching a glass substrate. The first glass substrate GL1 and the second glass substrate GL2 may be formed by providing an etchant to a glass substrate. The first glass substrate GL1 and the second glass substrate GL2, which are formed by using an etchant, may respectively have the inclined first sub-side surfaces GL1_S1 and GL2_S1 and the inclined second sub-side surfaces GL1_S2 and GL2_S2.

The polymer film GF may be disposed below the support plate SP. The polymer film GF may be formed from a polymer material having a flexible property. The polymer film GF may include at least one selected from polyethylene terephthalate (PET), polyimide (PI), polycarbonate (PC), polyethylene (PE), polypropylene (PP), polysulfone (PSF), poly(methyl methacrylate) (PMMA), triacetyl cellulose (TAC), and cyclo olefin polymer (COP).

The polymer film GF may overlap the first non-bending region NBA1, the bending region BA, and the second non-bending region NBA2. The polymer film GF may include a first flat portion FP1, a curved portion CP, and a second flat portion FP2. The first flat portion FP1, the curved portion CP, and the second flat portion FP2 may have an integral shape. The first flat portion FP1 may overlap the first non-bending region NBA1, and may not be bent when the display module DM is bent. The curved portion CP may overlap the bending region BA, and may be bent when the display module DM is bent. The second flat portion FP2 may overlap the second non-bending region NBA2, and may not be bent when the display module DM is bent.

In the first mode in which the display module DM is bent such that the first non-bending region NBA1 overlaps the second non-bending region NBA2, the curved portion CP (see FIG. 8) may be bent to have a curvature. In the second mode in which the display module DM is not bent, the curved portion CP may be in an unbent state.

In the second mode in which the display module DM is not bent, the second flat portion FP2, the curved portion CP, and the first flat portion FP1 may be sequentially disposed along the second direction DR2. In the second mode in which the display module DM is not bent, the first flat portion FP1 and the second flat portion FP2 may be spaced apart from each other with the curved portion CP therebetween. In the second mode in which the display module DM is not bent, the curved portion CP and the display module DM may be spaced apart from each other.

In an embodiment, the display device DD including the polymer film GF may effectively prevent a crack from occurring in the bending region BA, and improve an impact resistance. As described above, the display device DD according to an embodiment may include the first and second glass substrates GL1 and GL2 which are directly disposed below the display module DM.

In a display device including the first and second glass substrates GL1 and GL2, which are directly disposed below the display module DM, and not including the polymer film GF, a crack may occur in the bending region BA when the display module DM is bent. There is no component (that is, polymer film) which supports the display module DM below the display module DM, and thus components disposed in the bending region BA may be damaged when the display module DM is bent. Also, the display device not including the polymer film GF may be vulnerable to an impact when an impact is applied to the bending region BA, and the bending region BA may be sharply bent due to the impact. According to an embodiment of the invention, the display device DD may include the polymer film GF below the display module DM to stably support the bending region BA, the display module DM when the display module DM is bent, thereby effectively preventing damage to the bending region BA and exhibiting high impact resistance.

Although not illustrated, an adhesive layer may be disposed on and/or disposed below the polymer film GF. The adhesive layer may be disposed between components (support plate GP and/or lower module FL) adjacent to the polymer film GF. In an embodiment, for example, the adhesive layer may include a pressure sensitive adhesive (PSA). However, this is presented as an example, and an embodiment of the invention is not limited thereto.

A lower module FL may be disposed below the polymer film GF. The lower module FL may overlap the first non-bending region NBA1. The lower module FL may not overlap the bending region BA. In the second mode in which the display module DM is not bent, the lower module FL may not overlap the second non-bending region NBA2. In the first mode in which the display module DM illustrated in FIG. 8 is bent, the lower module FL may overlap the second non-bending region NBA2.

In an embodiment, for example, the lower module FL may include at least one selected from a cushion layer, a shielding layer, and a heat dissipation layer. However, a component included in the lower module FL is not limited thereto, and the lower module FL may further include other components in consideration of an operation, etc., of the display device DD.

One side edge FL_EG of the lower module FL may be disposed further outward than one side edge GL1_PT of the first glass substrate GL1. The one side edge GL1_PT of the first glass substrate GL1 may be an edge at which the second sub-side surface GL1_S2 of the first glass substrate GL1 and the lower surface GL1_DF of the first glass substrate GL1 are connected to each other. The one side edge FL_EG of the lower module FL is disposed further outward (or further toward the bending region BA) than the one side edge GL1_PT of the first glass substrate GL1, and thus the polymer film GF (see FIG. 8) disposed on the lower module FL may be bent to have a uniform curvature.

In a case where the one side edge FL_EG of the lower module FL is disposed further inward than the one side edge GL1_PT of the first glass substrate GL1, the polymer film GF (see FIG. 8) may not be stably bent, and thus the curved portion CP (see FIG. 8) may not effectively support the display module DM. In this case, a crack occurs in the bending region BA of the display module DM, and an impact resistance of the display device DD is deteriorated. In an embodiment, the display device DD, in which the one side edge FL_EG of the lower module FL is disposed further outward than the one side edge GL1_PT of the first glass substrate GL1, may effectively prevent a crack from occurring in the bending region BA, and exhibit high impact resistance.

FIG. 8 is a cross-sectional view illustrating a portion taken along line III-III′ of FIG. 3. FIG. 8 may be a cross-sectional view illustrating a display device DD in a first mode in which a display module DM is bent such that a first non-bending region NBA1 overlaps a second non-bending region NBA2.

Referring to FIG. 8, in the first mode in which the display module DM is bent, a curved portion CP may be bent to have a curvature. In the first mode, a first flat portion FP1 may face a second flat portion FP2. In the first mode, the first flat portion FP1 may overlap the second flat portion FP2. In the first mode, the first flat portion FP1 and the second flat portion FP2 may be spaced apart from each other with a lower module FL therebetween.

In the first mode, the curved portion CP may form a portion of a circumference of an oval or ellipse. A long axis (e.g., a major axis of symmetry) LX of the oval formed by the curved portion CP may be parallel to the second direction DR2 perpendicular to the thickness direction DR3. In FIG. 8, the long axis LX is illustrated as an imaginary line for convenience of description. In the first mode, a polymer film GF may have a dumbbell-like shape. In the first mode, the curved portion CP may correspond to one portion among protruding portions of a dumbbell, and the first flat portion FP1 and the second flat portion FP2 may correspond to a handle portion disposed between the protruding portions of the dumbbell.

In the first mode, a first glass substrate GL1 may overlap a second glass substrate GL2. In the first mode, the first glass substrate GL1 and the second glass substrate GL2 may be spaced apart from each other with a polymer film GF and the lower module FL therebetween. In an embodiment, as described above, the first glass substrate GL1 and the second glass substrate GL2 may be formed through an etching process and include the inclined first and second sub-side surfaces GL1_S1, GL2_S1, GL1_S2, and GL2_S2 (see FIG. 7). Accordingly, in the first mode, the polymer film GF may have a dumbbell-like shape. In the first mode, the polymer film GF may be bent in a dumbbell-like shape due to etched shapes of the first glass substrate GL1 and the second glass substrate GL2. When the display module DM is bent, the display module DM and the polymer film GF have different curvatures from each other, and the bent polymer film GF is in a limited space to be expanded due to the display module DM, and thus the polymer film GF may be bent in a dumbbell-like shape.

In the first mode, a bending-protective layer BPL may be bent to have a curvature. In the first mode, the bending-protective layer BPL may be spaced apart from the curved portion CP with the display module DM therebetween. In the first mode, a portion of the curved portion CP may be in contact with the display module DM.

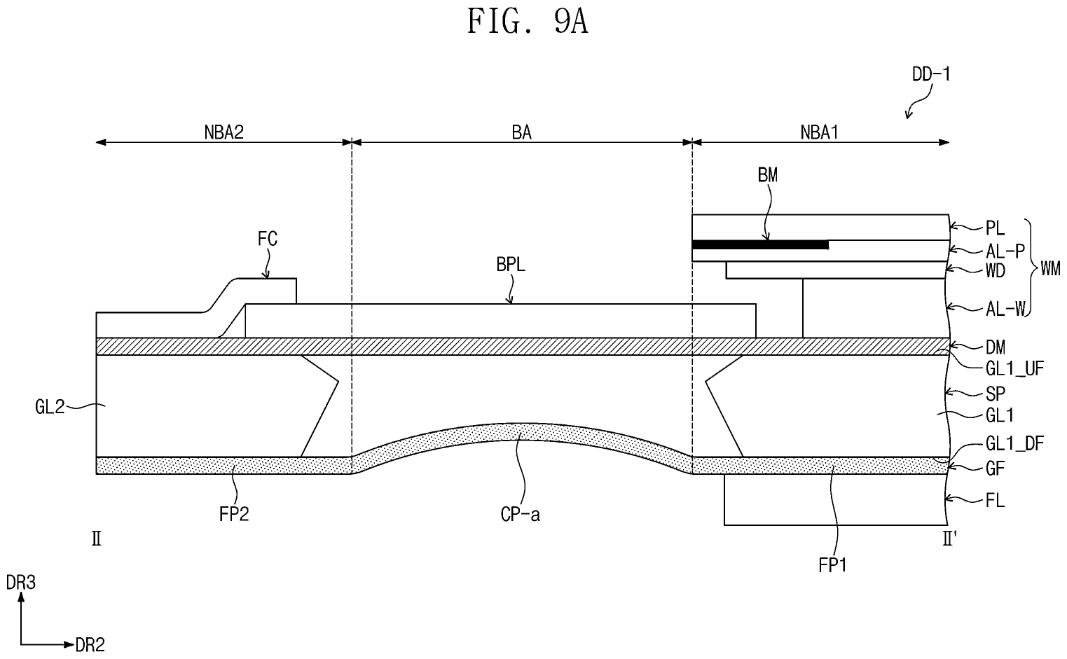

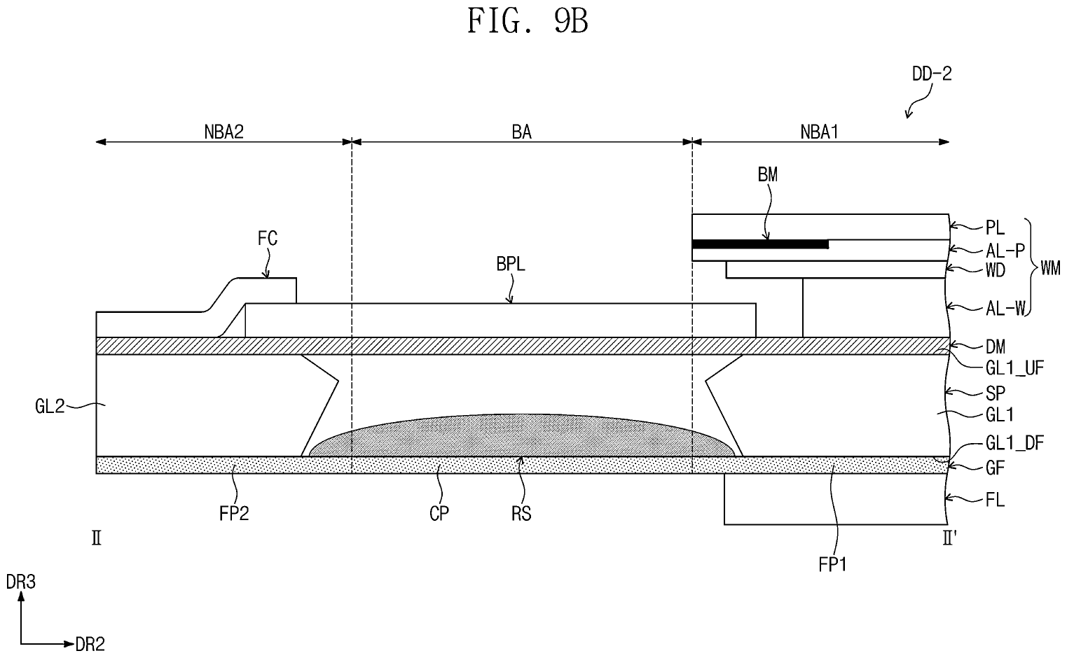

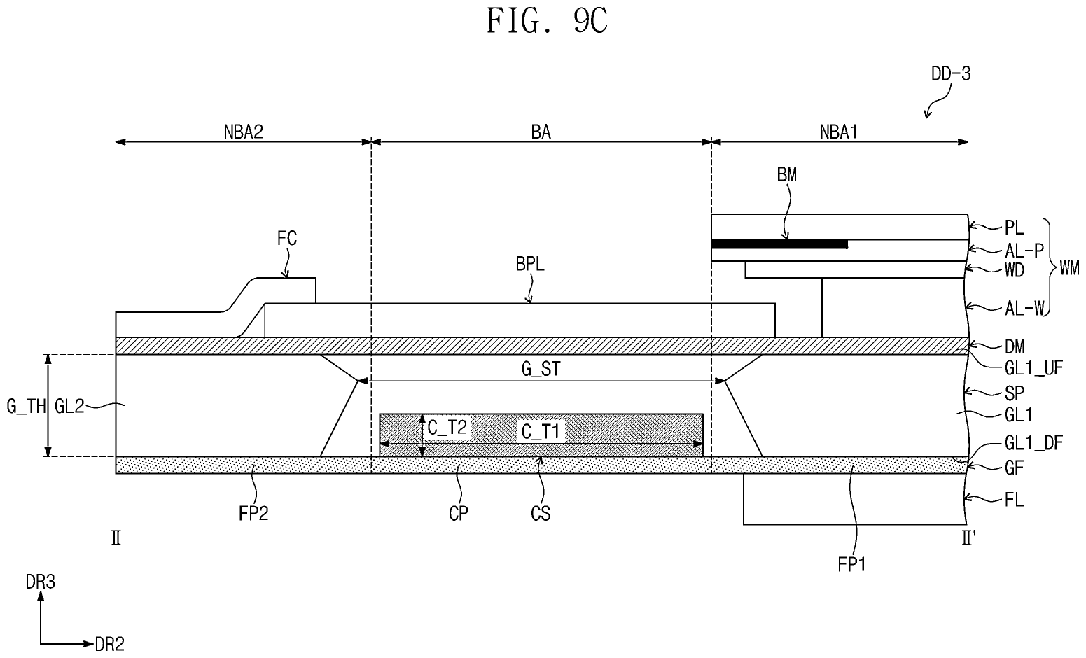

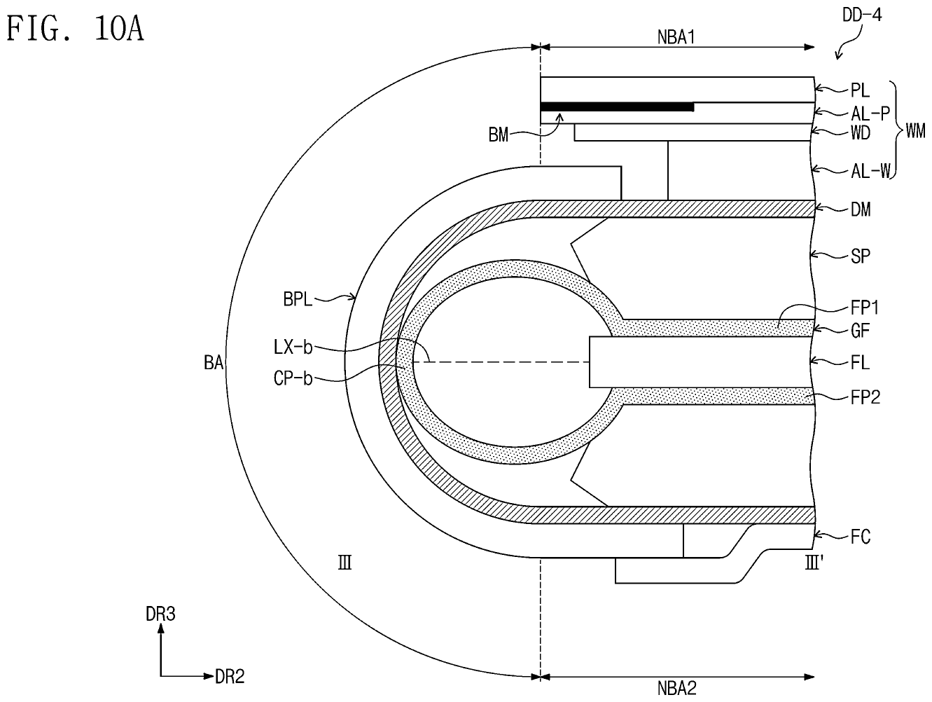

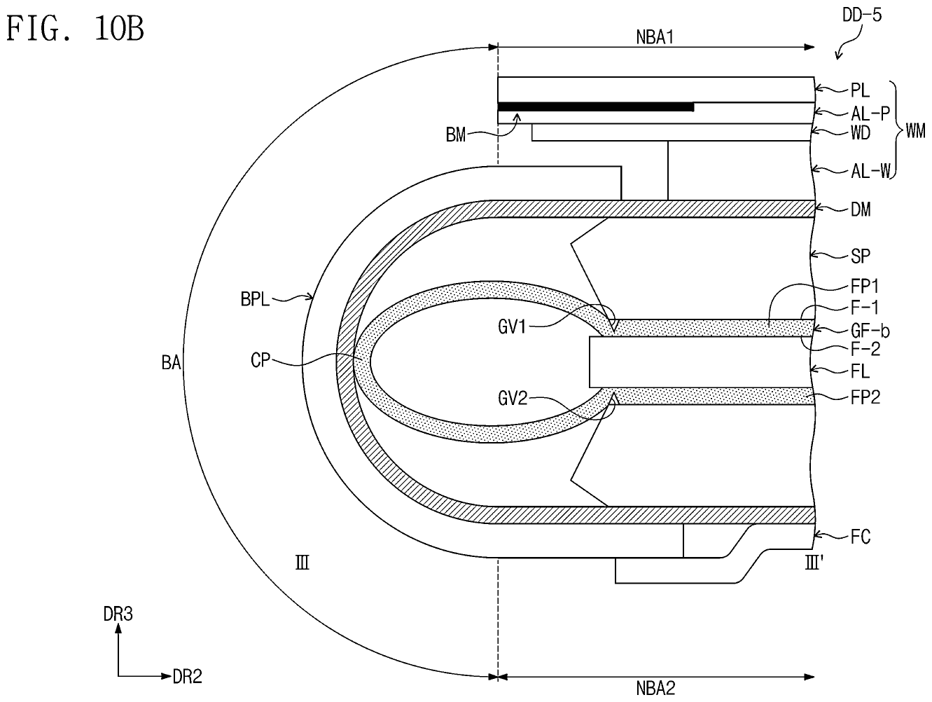

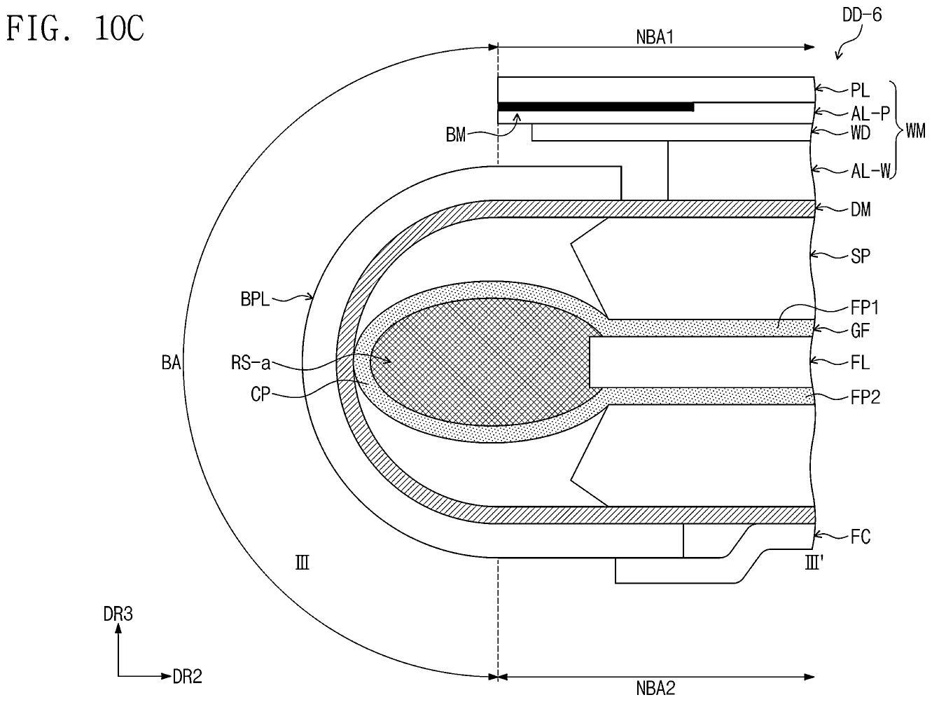

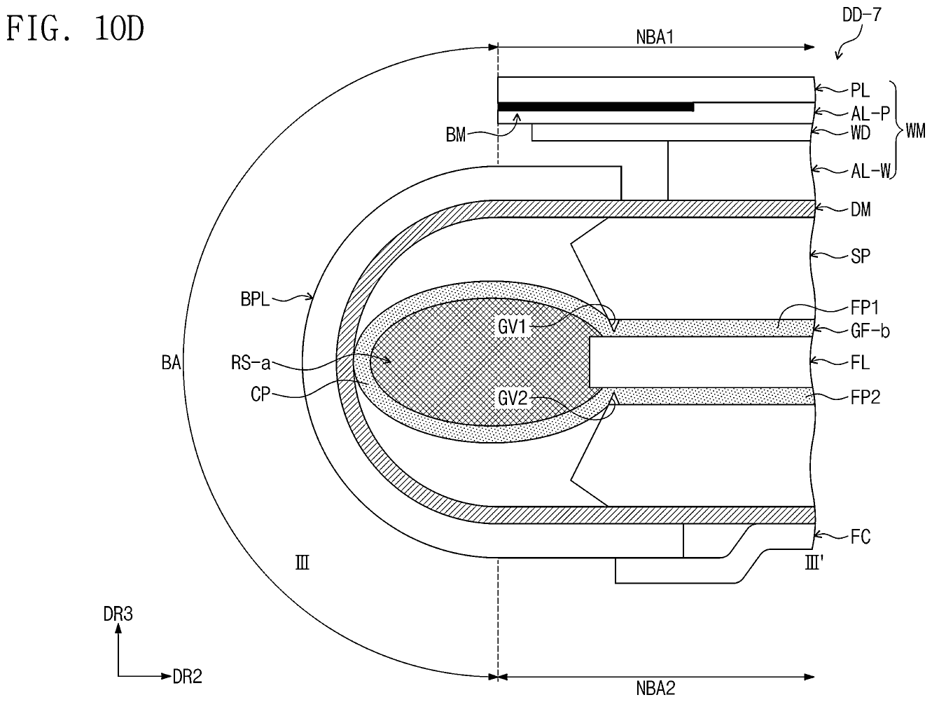

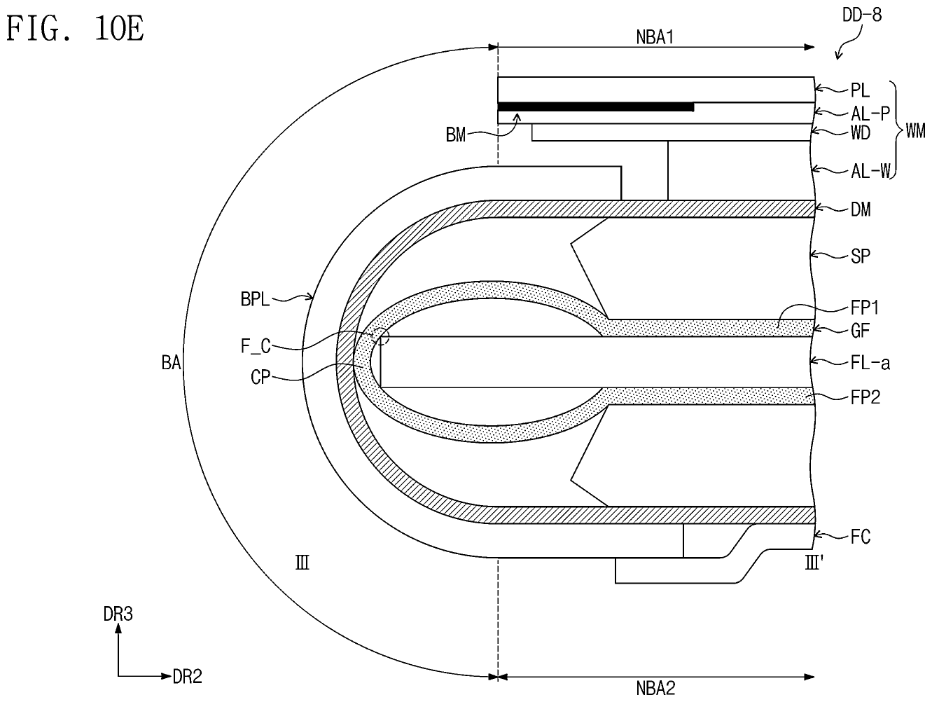

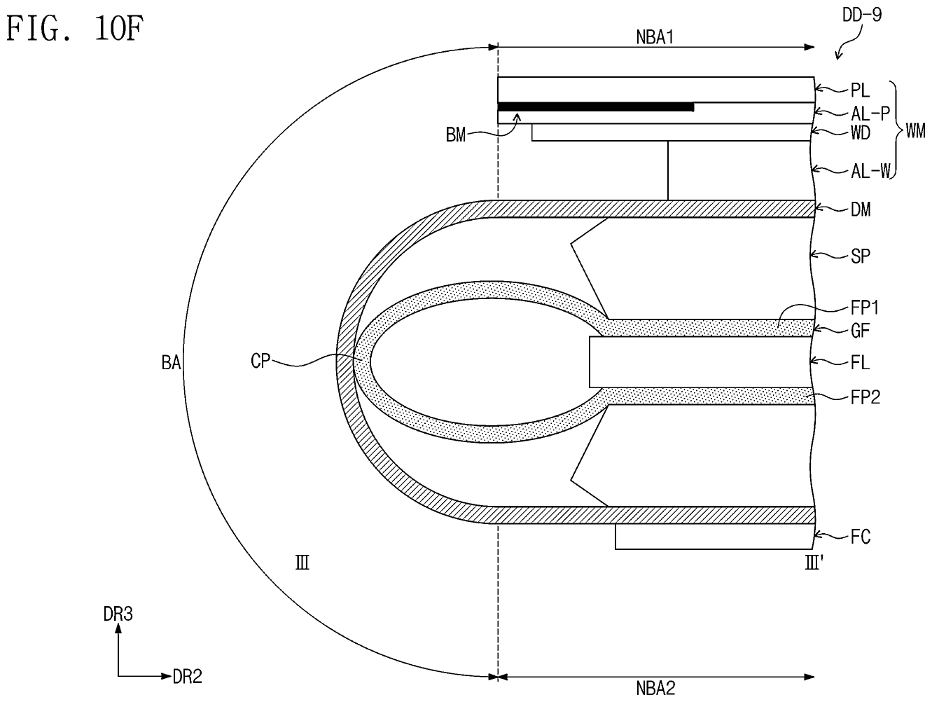

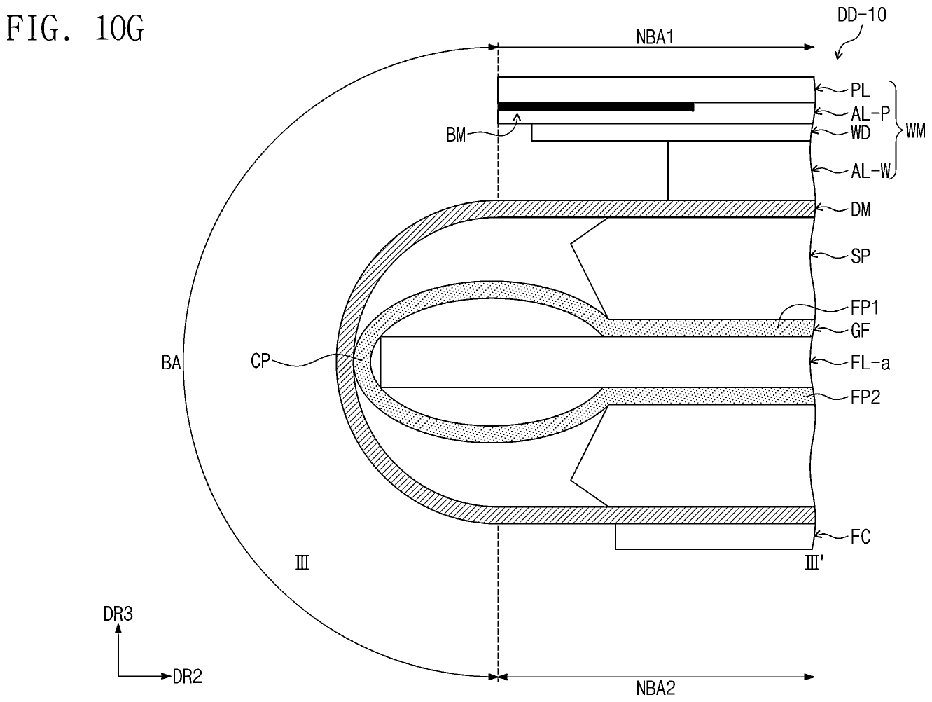

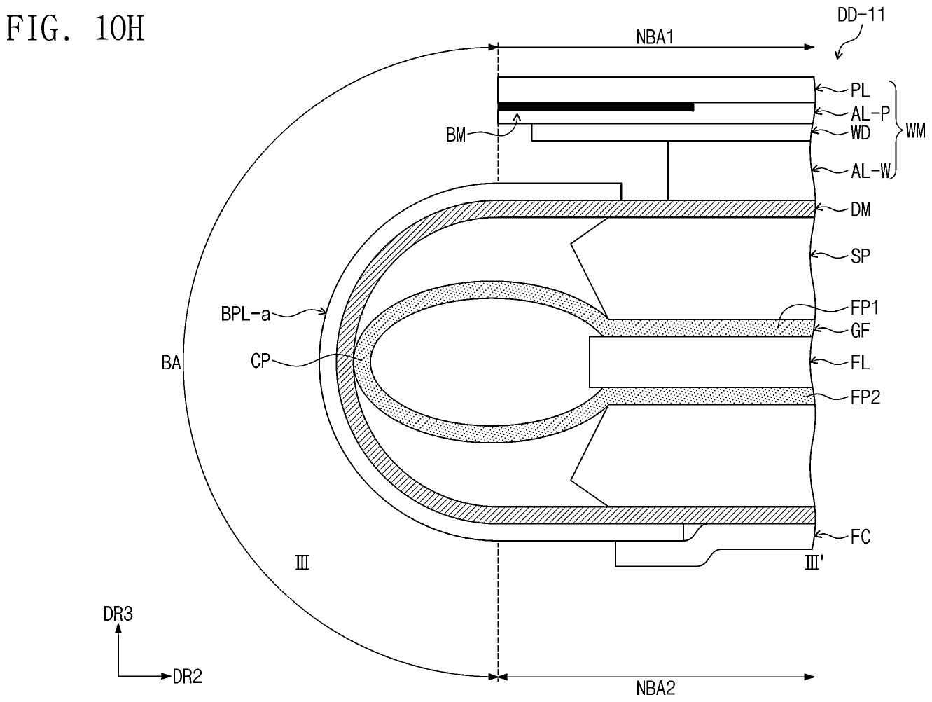

FIGS. 9A to 10H are cross-sectional views illustrating other embodiments of the invention. FIGS. 9A to 9C may be cross-sectional views illustrating embodiments of a display device DD-1, DD-2, and DD-3 in a second mode in which a display module DM is not bent. FIGS. 10A to 10H are cross-sectional views illustrating embodiments of a display device DD-4 to DD-11 in a first mode in which the display module DM is bent. Hereinafter, with regard to the descriptions of FIGS. 9A to 10H, any repetitive detailed description of the same or like elements as those described above with the references to FIGS. 1 to 8 will be omitted, and the following description will be mainly focused on the differences.

Referring to FIGS. 7 and 9A, the display device DD-1 illustrated in FIG. 9A is substantially the same as the display device DD illustrated in FIG. 7 except that the display device DD-1 includes a curved portion CP-a of a polymer film GF-a. In an embodiment, as shown in FIG. 7, the curved portion CP of the polymer film GF may have a same length as the bending region BA of the display module DM. In another embodiment, as shown in FIG. 9A, the length of the curved portion CP-a may be greater than the length of the bending region BA of the display module DM. Accordingly, in the second mode in which the display module DM is not bent, the curved portion CP-a may have a curved shape. As the length of the curved portion CP-a is increased, when the display module DM is bent, the point in time for the curved portion CP-a to support the display module DM is shortened, and a portion supporting the display module DM is increased in the curved portion CP-a, and thus the display module DM may be stably bent.

Referring to FIGS. 7 and 9B, the display device DD-2 illustrated in FIG. 9B is substantially the same as the display device DD illustrated in FIG. 7 except that the display device DD-2 further includes a first buffer layer RS. In an embodiment, as shown in FIG. 9B, the first buffer layer RS may be disposed on the curved portion CP. The first buffer layer RS may overlap the bending region BA. Edge regions of the first buffer layer RS may overlap a first non-bending region NBA1 and a second non-bending region NBA2. The first buffer layer RS may be formed by applying a polymer resin. In an embodiment, for example, the first buffer layer RS may include at least one selected from an acryl-based resin, a urethane-based resin, and a silicon-based resin. The curved portion CP may be spaced apart from the display module DM with the first buffer layer RS therebetween. In the first mode in which the display module DM is bent, the first buffer layer RS may be in contact with the display module DM. In an embodiment, for example, in the first mode, the first buffer layer RS may be disposed to fill a space between the display module DM and the curved portion CP.

When the display module DM is bent, the first buffer layer RS stably supports the display module DM and absorbs an external impact, and thus damage to the display module DM may be effectively prevented. Therefore, the display device DD-2, according to an embodiment, including the first buffer layer RS, may prevent a crack from occurring in the bending region BA, and exhibit high impact resistance.

Referring to FIGS. 7 and 9C, the display device DD-3 illustrated in FIG. 9C is substantially the same as the display device DD illustrated in FIG. 7 except that the display device DD-3 further includes a sub-cushion layer CS. In an embodiment, as shown in FIG. 9C, the sub-cushion layer CS may be disposed on the curved portion CP. In an embodiment, the sub-cushion layer CS may be formed from a same material as the polymer film GF. Alternatively, the sub-cushion layer CS may be formed from a material different from that of the polymer film GF, and in this case, the sub-cushion layer CS may include a foam or a sponge. However, this is presented as an example, and a material included in the sub-cushion layer CS is not limited thereto.

In the thickness direction DR3, the thickness C_T2 of the sub-cushion layer CS may be less than the thickness G_TH of a support plate SP. In the second direction DR2 perpendicular to the thickness direction DR3, the length C_T1 of the sub-cushion layer CS may be less than the minimum spacing distance G_ST between a first glass substrate GL1 and a second glass substrate GL2. The minimum spacing distance G_ST, between the first glass substrate GL1 and the second glass substrate GL2, may be a distance between the outermost location of the first glass substrate GL1 and the outermost location of the second glass substrate GL2, which face each other. The sub-cushion layer CS have the thickness C_T2 and length C_T1 that satisfy the above-described conditions, respectively, and thus the display module DM may be stably supported when being bent.

Referring to FIGS. 8 and 10A, the display device DD-4 illustrated in FIG. 10A is substantially the same as the display device DD illustrated in FIG. 8 except that the display device DD-4 includes a curved portion CP-b, of a polymer film GF, having a different shape. Specifically, the curved portion CP-b illustrated in FIG. 10A differs from the curved portion CP illustrated in FIG. 8 in that a length of a long axis LX-b of the curved portion CP-b is shortened. In FIG. 10A, the long axis LX-b is illustrated as an imaginary line for convenience of illustration and description. The length of the long axis LX-b may be shortened by tightly bending the polymer film GF. As the length of the long axis LX-b is shortened, a portion in which the curved portion CP-b and a support plate SP come into contact with each other may be increased.

Referring to FIGS. 8 and 10B, the display device DD-5 illustrated in FIG. 10B is substantially the same as the display device DD illustrated in FIG. 8 except that the display device DD-5 includes a polymer film GF-b in which first and second grooves GV1 and GV2 are defined. In an embodiment, as shown in FIG. 10B, the first groove GV1 may be defined between a first flat portion FP1 and a curved portion CP, and the second groove GV2 may be defined between a second flat portion FP2 and the curved portion CP.

In the thickness direction DR3, the first and second grooves GV1 and GV2 be defined or formed through only a portion of the polymer film GF-b. The first and second grooves GV1 and GV2 may be defined or formed on one surface F-1 of the polymer film GF-b adjacent to the support plate SP, and may not be defined or formed through the other surface F-2 of the polymer film GF-b adjacent to a lower module FL. The one surface F-1 and the other surface F-2 of the polymer film GF-b may be spaced apart from each other in the thickness direction DR3.

Referring to FIGS. 8 and 10C, the display device DD-6 illustrated in FIG. 10C is substantially the same as the display device DD illustrated in FIG. 8 except that the display device DD-6 includes a second buffer layer RS-a. In an embodiment, as shown in FIG. 10C, in the first mode in which the display module DM is bent, the second buffer layer RS-a may be disposed to fill an inner space formed by the curved portion CP. The second buffer layer RS-a may be formed by applying a polymer resin. In such an embodiment, in the second mode in which the display module DM is not bent, the second buffer layer RS-a may be applied to a lower surface of the curved portion CP and be temporarily cured. Thereafter, the temporarily cured polymer resin is mainly cured in the first mode in which the display module DM is bent, and then the second buffer layer RS-a may be formed. In an embodiment, for example, the second buffer layer RS-a may include at least one selected from an acryl-based resin, a urethane-based resin, and a silicon-based resin. The second buffer layer RS-a may maintain a curvature of the curved portion CP and absorb an external impact, thereby preventing damage to the display device DD-6. Therefore, the display device DD-6, according to an embodiment, including the second buffer layer RS-a may exhibit an excellent impact resistance.

Referring to FIGS. 8 and 10D, the display device DD-7 illustrated in FIG. 10D is substantially the same as the display device DD illustrated in FIG. 8 except that the display device DD-7 includes first and second grooves GV1 and GV2 defined therein and a second buffer layer RS-a. In an embodiment of the display device DD-7, as illustrated in FIG. 10D, the first and second grooves GV1 and GV2, which are illustrated in FIG. 10B, may be defined, and the second buffer layer RS-a, which is illustrated in FIG. 10C, may be included. The contents described with the references to FIGS. 10B and 10C may be similarly applied to the first and second grooves GV1 and GV2, and the second buffer layer RS-a, which are illustrated in FIG. 10D.

Referring to FIGS. 8 and 10E, the display device DD-8 illustrated in FIG. 10E is substantially the same as the display device DD illustrated in FIG. 8 except that at least a portion F_C of a lower module FL-a of the display device DD-8 is in contact with the polymer film GF. Specifically, a length of the lower module FL-a illustrated in FIG. 10E may be increased in the second direction DR2, compared to the lower module FL illustrated in FIG. 8. In such an embodiment, as the length of the lower module FL-a is relatively increased, at least the portion F_C of the lower module FL-a may be in contact with the polymer film GF. The lower module FL-a having an increased length stably supports the polymer film GF, and thus the display device DD-8 according to an embodiment may exhibit high or improved impact resistance.

Referring to FIGS. 8 and 10F, the display device DD-9 illustrated in FIG. 10F is substantially the same as the display device DD illustrated in FIG. 8 except that the display device DD-9 does not include the bending-protective layer BPL (see FIG. 8). In such an embodiment, since the polymer film GF stably supports the display module DM to prevent the occurrence of cracks in the bending region BA and to improve an impact resistance, the bending-protective layer BPL may be omitted.

Referring to FIGS. 8 and 10G, the display device DD-10 illustrated in FIG. 10G is substantially the same as the display device DD illustrated in FIG. 8 except that the display device DD-10 does not include the bending-protective layer BPL, and a length of a lower module FL-a thereof is increased. In an embodiment, as shown in FIG. 10G, the display device DD-10 may not include the bending-protective layer BPL, similarly to the display device DD-9 of FIG. 10F, and include the lower module FL-a illustrated in FIG. 10E. The lower module FL-a may have a length increased in the second direction DR2. The contents described with the references to FIGS. 10E and 10F may be similarly applied to the description of FIG. 10G.

Referring to FIGS. 8 and 10H, the display device DD-11 illustrated in FIG. 10H is substantially the same as the display device DD illustrated in FIG. 8 except that the display device DD-11 includes a bending-protective layer BPL-a having a thin thickness. In an embodiment, as shown in FIG. 10H, since the polymer film GF stably supports the display module DM to prevent the occurrence of cracks in the bending region BA and to improve an impact resistance, the bending-protective layer BPL-a having a relatively thin thickness may be provided.

A display device according to an embodiment may include a display module including a bending region, a support plate disposed below the display module, and a polymer film disposed below of the support plate. The polymer film may include a curved portion which is bent when the display module is bent, and the curved portion may be bent to have a curvature. A display device, according to an embodiment, including a polymer film may effectively prevent a crack from occurring in a bending region, and exhibit high or improved impact resistance.

A display device according to an embodiment may include a polymer film which is bent to have a curvature, thereby effectively preventing occurrence of a crack in a bending region, and exhibiting high or improved impact resistance.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a display module including a first non-bending region, a bending region adjacent to the first non-bending region, and a second non-bending region spaced apart from the first non-bending region with the bending region therebetween;
a support plate disposed below the display module, wherein the support plate includes a first glass substrate and a second glass substrate which are spaced apart from each other in one direction perpendicular to a thickness direction; and
a polymer film disposed below the support plate, wherein the polymer film includes a first flat portion, a curved portion, which extends from the first flat portion and overlaps the bending region, and a second flat portion which extends from the curved portion and is spaced apart from the first flat portion,
wherein a state, in which the display module is bent such that the first non-bending region overlaps the second non-bending region, is defined as a first mode, and a state, in which the display module is not bent, is defined as a second mode, and
in the first mode, the curved portion is bent to have a curvature.

2. The display device of claim 1, wherein in the first mode, the curved portion forms a portion of a circumference of an oval, and a major axis of the oval is parallel to the one direction.

3. The display device of claim 1, wherein the bending region is a non-display region in which an image is not displayed.

4. The display device of claim 1, wherein in the first mode, the curved portion is in contact with the display module, and
in the second mode, the curved portion is spaced apart from the display module.

5. The display device of claim 1, wherein in the first mode, the first flat portion overlaps the second flat portion.

6. The display device of claim 1, wherein a length of the curved portion of the polymer film is greater than a length of the bending region of the display module.

7. The display device of claim 1, further comprising:
a first buffer layer disposed on the curved portion.

8. The display device of claim 1, wherein in the polymer film, a first groove is defined between the first flat portion and the curved portion, and a second groove is defined between the second flat portion and the curved portion.

9. The display device of claim 8, wherein in the thickness direction, the first groove and the second groove is defined through only a portion of the polymer film.

10. The display device of claim 1, further comprising:
a second buffer layer disposed below the curved portion,
wherein in the first mode, the second buffer layer is disposed to fill an inner space formed by the curved portion.

11. The display device of claim 1, further comprising:
a sub-cushion layer disposed on the curved portion,
wherein in the one direction, a length of the sub-cushion layer is less than a minimum spacing distance between the first glass substrate and the second glass substrate.

12. The display device of claim 11, wherein a thickness of the sub-cushion layer is less than a thickness of the support plate.

13. The display device of claim 1, further comprising:
a lower module disposed below the polymer film,
wherein in the first mode, at least a portion of the lower module is in contact with the polymer film.

14. The display device of claim 1, wherein
the first glass substrate overlaps the first non-bending region,
the second glass substrate overlaps the second non-bending region, and
the first glass substrate and the second glass substrate do not overlap the bending region.

15. The display device of claim 1, wherein each of the first glass substrate and the second glass substrate comprise an upper surface, a lower surface opposite to the upper surface, and a side surface disposed between the upper surface and the lower surface, and
the side surface comprises a first sub-side surface inclined with respect to the upper surface, and a second sub-side surface inclined with respect to the first sub-side surface and the lower surface.

16. The display device of claim 15, further comprising:
a lower module disposed below the polymer film,
wherein one side edge of the lower module is disposed outside an edge at which the second sub-side surface and the lower surface are connected to each other.

17. The display device of claim 1, wherein the polymer film comprises at least one selected from polyethylene terephthalate (PET), polyimide, (PI), polycarbonate (PC), polyethylene (PE), polypropylene (PP), polysulfone (PSF), poly(methyl methacrylate) (PMMA), triacetyl cellulose (TAC), and cyclo olefin polymer (COP).

18. The display device of claim 1, further comprising:
a bending-protective layer disposed on the display module,
wherein in the first mode, the bending-protective layer is bent to have a curvature.

19. The display device of claim 18, wherein in the first mode, the bending-protective layer is spaced apart from the curved portion with the display module therebetween.

20. The display device of claim 1, wherein the display module comprises a base layer, a circuit layer disposed on the base layer, and a display element layer disposed on the circuit layer.
